(19) United States
(12) Patent Application Publication
(10) Pub. No.: US 2016/0005653 A1
(43) Pub. Date: Jan. 7, 2016

(54) FLEXIBLE WAFER-LEVEL CHIP-SCALE PACKAGES WITH IMPROVED BOARD-LEVEL RELIABILITY

(71) Applicant: NXP B.V., Eindhoven (NL)

(72) Inventors: Caroline Catharina Maria Beelen-Hendrikx, Nijmegen (NL); Tonny Kamphuis, NIijmegen (NL); Leonardus Antonius Elisabeth van Gemert, NIijmegen (NL)

(21) Appl. No.: 14/322,304

(22) Filed: Jul. 2, 2014

(51) Int. Cl. H01L 21/78; H01L 21/683; H01L 23/00; H01L 21/304

(52) U.S. Cl. CPC H01L 21/78; H01L 21/304; H01L 21/6836; H01L 24/14

(57) ABSTRACT

Consistent with an example embodiment, there is a method for manufacturing integrated circuit (IC) devices from a wafer substrate, the wafer substrate having a front-side surface with active devices and a back-side surface. A temporary covering to the front-side of the wafer substrate is applied. The back-side of the wafer substrate having a pre-grind thickness is ground to a post-grind thickness. To a predetermined thickness, the back-side of the wafer substrate is coated with a resilient coating. The wafer is mounted onto a second carrier tape on its back-side surface. After removing the temporary carrier tape from the front-side of the wafer substrate, the wafer is sawed along active device boundaries and active devices are singulated.

### FIELD

The embodiments described herein relate to the preparing of semiconductor wafers for wafer-level chip-scale packaging (WLCSP). In particular, the embodiments involve the reducing of the thickness of the wafer substrate so that resulting active devices achieve a lower thickness which in turn enhances their reliability when assembled onto printed circuit board systems.

### BACKGROUND

The assembly of WLCSP devices is trending towards a lower vertical profile and increasingly larger circuit arrays. In one example process, smaller solder bumps may be used to reduce the vertical height of the circuit. However, smaller bumps and larger arrays may lead to worse board-level reliability issues. Such issues may involve, environmental and mechanical stresses, that a board-level sub-assembly may encounter in portable electronic devices, such as mobile phones, tablet computers, etc. Or the board-level sub-assembly may be part of automotive electronics with its own severe environmental and mechanical stresses. In another example process, the use of a thinner substrate containing the circuit arrays may enhance board-level reliability owing to the thinner substrate's increased mechanical flexibility. However, there may be an additional risk of the thinner substrate cracking owing to mechanical stress.

However, there are challenges in the processing and handling of these thinner substrates. There exists a need to overcome these shortcomings in using these thinner substrates in improving board-level reliability.

### SUMMARY

As one thins out the wafer substrate in reducing the vertical profile of finished WLCSP devices installed on printed circuit board (PCB) subsystems, he needs to be aware that the susceptibility of the integrated circuit devices to breakage increases. The application of a resilient coating to the underside of a thinned wafer substrate (having undergone a back-grinding process) containing active devices serves to reduce the likelihood breakage of the substrate. Consequently, as individual devices (the individual devices having solder bumps) are mounted to the PCB, the individual devices are better able to withstand the environment rigors of the PCB application and yet have a thinner profile so as not to consume valuable space.

A resilient coating enhances stability to the device so that it still can be handled although the silicon is very thin. Further, when the properties of the resilient coating are matched to those of a PCB (to which it is mounted), the resilient back-side coated substrate will improve board level reliability. Board level reliability is enhanced and exceeds that of an un-thinned device, not having the resilient coating.

In an example embodiment, there is a method for manufacturing integrated circuit (IC) devices from a wafer substrate. The wafer substrate has a front-side surface with active devices and a back-side surface. On the front-side of the wafer substrate, a temporary covering is applied. The temporary covering may be a resilient coating or a temporary carrier tape. Through back-grinding, the back-side of the wafer substrate, having a pre-grind thickness, is ground to a post-grind thickness. After back-grinding, the back-side of the wafer substrate is coated, to a predetermined thickness, with a resilient coating. The wafer substrate is mounted onto a second carrier tape on the coated back-side surface; temporary carrier tape on the front-side surface of the wafer substrate is removed. Along active device boundaries, the wafer substrate is sawed and active devices are singulated. Each singulated device has a resilient surface in its back-side surface.

A feature of this embodiment further comprises, prior to applying the temporary covering, the method further comprises, applying and patterning a dielectric layer on the front-side surface of the wafer substrate, applying and patterning an RDL layer, applying and patterning a dielectric layer on the front-side surface of the wafer substrate, applying and patterning the under bump metallization, and applying bumps.

In another example embodiment, there is a method for preparing a silicon-on-insulator (SOI) substrate, for manufacturing IC devices, the SOI substrate having a front side surface and back-side surface opposite the front side surface. The method comprises, providing an SOI substrate with active devices patterned on the front-side surface of the SOI substrate. There is a grinding down the back-side surface of the SOI substrate so as to obtain a first thickness of the SOI substrate. The front-side surface of the SOI substrate is protected with an etch-resistant coating. The back-side surface of the SOI substrate surface is etched so as to obtain a final thickness. A resilient coating of a thickness is applied to the back-side surface of the SOI substrate. A feature of this embodiment includes that the final thickness of the SOI substrate is defined by a depth of a buried layer etch stop. The final SOI thickness obtained may be about 3 μm. With a resilient coating applied, the vertical profile of a completed SOI device may be less than about 35 μm.

In an example embodiment, there is an integrated circuit (IC) device for wafer-level chip-scale packaging (WLCSP). The IC device comprises a device die with a front-side surface with an active device and a back-side surface, wherein the back-side surface has been ground to a post-grind thickness. A resilient coating, of a thickness adheres to the back-side surface of the IC. The post-grind thickness of the device die and the thickness of the resilient coating are defined such that the coefficient of expansion of the IC device is similar to that of a printed circuit board (PCB) to which the IC device is mounted.

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments disclosed in connection with the accompanying drawings, in which:

FIG. 1 is a flow diagram of an example process in accordance with the present disclosure; and

FIGS. 2A-2E is a series of diagrams illustrating the application of a resilient coating on the under-side of a wafer substrate in accordance with the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful manufacturing electronic devices having a narrower vertical profile (i.e., the device thickness in the “Z” direction). The narrower vertical profile becomes a significant factor in the assembly of systems of smaller form factors and increased performance. For example, in the evolution of smart phone devices, one manufacturer's device thickness in one generation is about 9.4 mm; the thickness of the subsequent generation is about 7.6 mm, a 20% reduction. The reduction is only achieved through the miniaturization of components needed to build the smart phone apparatus. Achieving a narrower vertical profile involves the grinding off of unnecessary silicon material from the back-side of the wafer substrate. However, the resulting thinner substrate is more susceptible to breakage during handling. The application of a resilient coating on the back-side of the thinned substrate provides protection during handling during assembly. Further, the thinner, back-side coated substrate provides for more mechanical flexibility of the device as it is mounted onto the system printed circuit board (PCB). The device may flex without mechanical damage in response to thermal cycling of the system through normal use and environmental stresses.

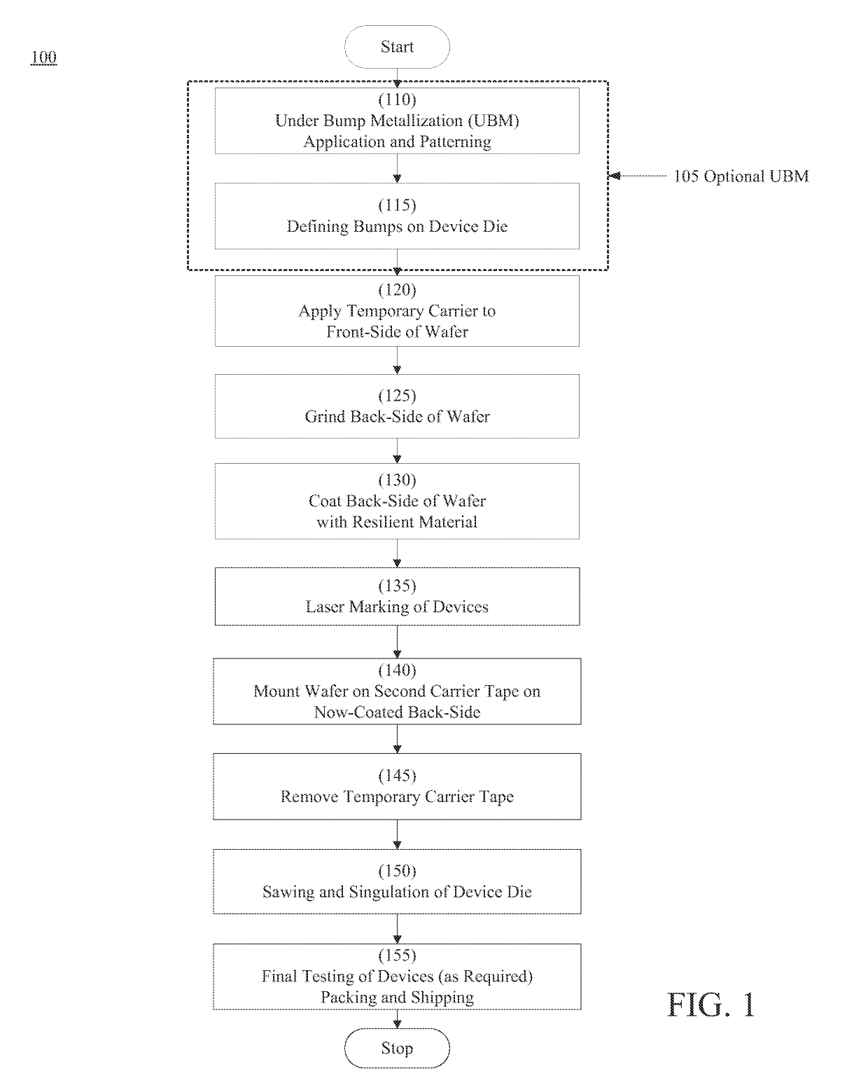

Refer to FIG. 1. In an example embodiment, according the disclosure, a process 100 may begin with optional bumping steps 105. This can be for a re-passivation (bump on I/O or redistribution process. A passivation process starts with dielectric application and patterning on a wafer substrate having active device die. Patterning is done by photolithography. Under bump metallization (UBM) is applied by sputtering of metal or through a plating process, the particular areas defined through patterning by a photolithographic process or other suitable techniques 110. An example process of making UBM may be found in U.S. Pat. No. 8,093,097 of Thomas Lange et al, titled, “Layer Sequence and Method of Manufacturing a Layer Sequence,” granted on Jan. 10, 2012 and assigned to NXP B.V., Eindhoven, Netherlands, and is incorporated by reference in its entirety. The UBM ensures proper adhesion to the bump pad on the die, act as a barrier layer and ensures solderability. Dielectric and UBM are steps in a bumping process applied by bumping subcontractors. After UBM, the wafer has bumps applied thereon 115. Bumping may be done by ball drop, printing, or plating. After solder bump application, the wafer substrate is mounted on its front-side, onto a temporary carrier 120 (e.g., a silicon or glass carrier). The temporary carrier permits the wafer substrate to undergo processing to implement the disclosed features. The wafer substrate undergoes back-grinding 125 to a thickness in a range of about 25 μm to about 50 μm.

In another example embodiment, prior to the UBM, a device's I/O pad positions may not conform to those defined on a system board to which the device is mounted. Consequently, a redistribution layer (RDL) may be used. For example, for large device die, the finished device may have an array of solder balls, for example a 10×10 array; the pitch between bumps is about 0.4 mm. A first layer of dielectric is applied to the device. An RDL metallization layer re-routes the I/O pads to new positions on the 10×10 array. A second dielectric layer provides a protective passivation for the RDL metallization. An UBM application and pattern completes the process prior to the placement of solder bumps. Such a technique enables one standard product device designed for wire-bonding to be used for WLCSP and it improves the board level reliability.

In contrast with the disclosed example processes, a wafer thickness for a 200 mm (“8 inch” with pre-grind thickness of about 725 μm), after back-grind, is about 150 μm to about 360 μm. For a 300 mm (“12 inch” with a pre-grind thickness of about 775 μm), after back-grind, a wafer thickness is in the range of about 225 μm to about 360 μm.

In an example process the post-grind thickness may be in the range of about 4% to about 10%. For 200 mm wafer, the post-grind thickness would be in the range about 30 μm to about 73 μm. For a 300 mm wafer, the post grind thickness would be in the range of about 30 μm to about 78 μm.

Through a lamination or printing process, the resilient coating of about 100 μm to about 300 μm is applied to the back-side of the wafer substrate 130. The resilient coating may be an epoxy molding compound or an epoxy-based back-side coating material. Depending on the particular material properties even thinner layers might be used. Silicone-based materials may be suitable, as well. The resilient coating, may also be made of, but not necessarily limited to, KAPTON®, PTFE (polytetrafluoroethylene), and other types of molding compound, etc. KAPTON is the brand name of the polyimide film (i.e., poly-oxydiphenylene-pyromellitimide) manufactured by the E.I. du Pont de Nemours and Company. Other flexible protective materials may include, but not necessarily limited to, polytetra-fluoroethylene. Some molding compounds, may include, but not necessarily limited to, those manufactured by Sumitomo (e.g.: x84194) and Hitachi (e.g.: cel 400 ZHF 40 53 C), etc. The resilient material may be epoxy-based. In another example process, a spin-on silicone-based coating may be used.

The resilient coating in terms of expansion coefficient should be close to that of the printed circuit board to which the finished product device is mounted. In one example embodiment, the silicon wafer substrate may be thinned to about 30 um and a coating of about 30 μm to about 150 μm of poly-benzyl methacrylate. In another example embodiment, the resilient coating thickness range may be about 30 μm to about 200 μm.

The wafer-substrate after coating is then laser marked at device die locations, to delineate the individual device die 135. After marking, the wafer substrate is mounted onto a second carrier tape (dicing tape), the now-coated back-side covered by the tape 140. The temporary carrier is removed, as well 145. In another example embodiment, the resilient coating is laminated onto the wafer; this laminated coating may act as a second carrier tape in lieu of a dicing tape. The wafer substrate undergoes sawing and singulation of device die 150. The singulated device die undergo a “final testing” and are packed and shipped to the end-user 155. The device die may be on tape and reel, waffle packs, or other configuration per the customer's requirements.

TABLE 1
Wafer Substrate Thicknesses to be Thinned

| | Pre-Grind | Range of Post-Grind |
|---|---|---|
| Wafer Size (Silicon Substrate) | Thickness (μm) | Thickness (μm) |
| 5-inch (130 mm) or 125 mm | 625 | 25 μm-62.5 μm |
| (4.9 inch). | | |
| 150 mm (5.9 inch, usually | 675 | 27 μm-67.5 μm |
| referred to as “6 inch”). | | |
| 200 mm (7.9 inch, usually | 725 | 29 μm-72.5 μm |
| referred to as “8 inch”). | | |
| 300 mm (11.8 inch, usually | 775 | 31 μm-77.7 μm |
| referred to as “12 inch”). | | |
| 450 mm (17.7 inch, usually | 925 (expected). | 37 μm-92.5 μm |
| referred to as “18 inch”). | | |

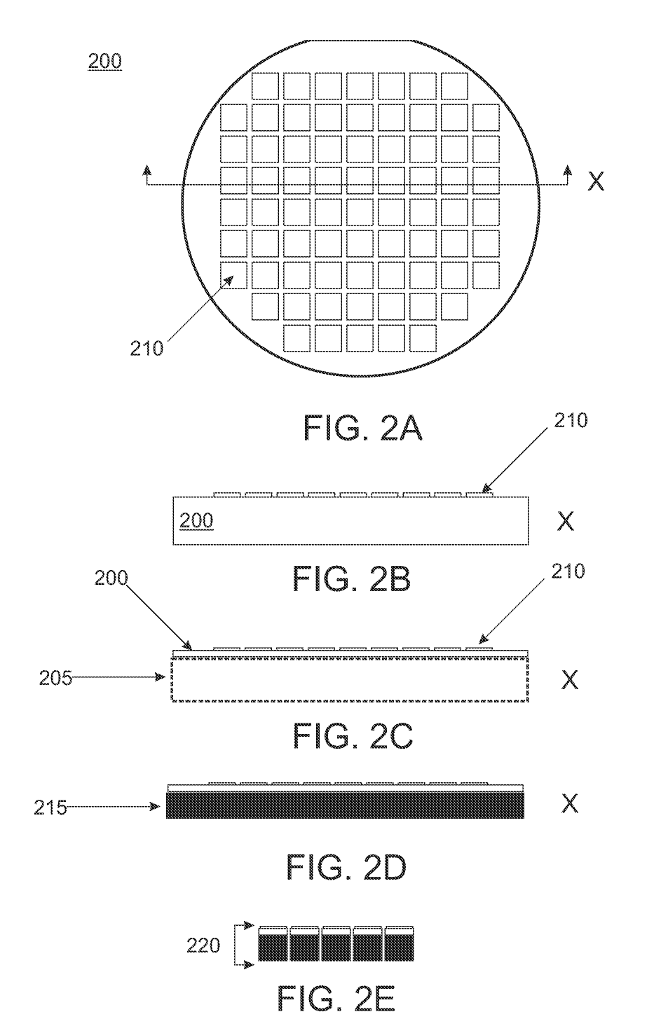

Refer to FIGS. 2A-2E. A wafer substrate 200 with a plurality of device die 210 is selected. If required, the wafer substrate 200 would undergo under bump metallization (UBM) to define and apply solder bumps (as discussed in relation to FIG. 1). The wafer undergoes a back-grinding 205 to remove a predetermined amount of material, as shown by the dashed lines. The wafer is sufficiently thinned out and will flex. Table 1 lists the amount of material that may be removed for a given wafer diameter. After back-grinding, a resilient coating 215 of an appropriate thickness is applied. The coated thinned wafer substrate 200 with a plurality of device die 210 is sliced apart into individual devices 220. The resilient coating enables the device die 220 to flex in response to environmental changes of the system board to which the device die 220 is soldered.

In another example embodiment, silicon-on-insulator (SOI) wafer substrates may be used. The wafer substrate may be as thin as about 3 μm. The SOI substrate is ground-down to about 25 μm. An etching process which uses the buried oxide layer as an etch stop, achieves this thickness.

In another example embodiment, the substrate may be SiC, GaAs, GaN, or InP; each substrate would have their own post-grind thickness limitations. For example, GaAs may undergo back-grinding to a thickness of about 100 μm.

Various exemplary embodiments are described in reference to specific illustrative examples. The illustrative examples are selected to assist a person of ordinary skill in the art to form a clear understanding of, and to practice the various embodiments. However, the scope of systems, structures and devices that may be constructed to have one or more of the embodiments, and the scope of methods that may be implemented according to one or more of the embodiments, are in no way confined to the specific illustrative examples that have been presented. On the contrary, as will be readily recognized by persons of ordinary skill in the relevant arts based on this description, many other configurations, arrangements, and methods according to the various embodiments may be implemented.

To the extent positional designations such as top, bottom, upper, lower have been used in describing this disclosure, it will be appreciated that those designations are given with reference to the corresponding drawings, and that if the orientation of the device changes during manufacturing or operation, other positional relationships may apply instead. As described above, those positional relationships are described for clarity, not limitation.

The present disclosure has been described with respect to particular embodiments and with reference to certain drawings, but the invention is not limited thereto, but rather, is set forth only by the claims. The drawings described are only schematic and are non-limiting. In the drawings, for illustrative purposes, the size of various elements may be exaggerated and not drawn to a particular scale. It is intended that this disclosure encompasses inconsequential variations in the relevant tolerances and properties of components and modes of operation thereof. Imperfect practice of the invention is intended to be covered.

Where the term “comprising” is used in the present description and claims, it does not exclude other elements or steps. Where an indefinite or definite article is used when referring to a singular noun, e.g. “a” “an” or “the”, this includes a plural of that noun unless something otherwise is specifically stated. Hence, the term “comprising” should not be interpreted as being restricted to the items listed thereafter; it does not exclude other elements or steps, and so the scope of the expression “a device comprising items A and B” should not be limited to devices consisting only of components A and B. This expression signifies that, with respect to the present disclosure, the only relevant components of the device are A and B.

Numerous other embodiments of the invention will be apparent to persons skilled in the art without departing from the spirit and scope of the invention as defined in the appended claims.

1. A method for manufacturing integrated circuit (IC) devices from a wafer substrate, the wafer substrate having a front-side surface with active devices and a back-side surface, the method comprising:
applying a temporary covering to the front-side of the wafer substrate;
grinding the back-side of the wafer substrate having a pre-grind thickness to a post-grind thickness;
coating the back-side of the wafer substrate with a resilient coating, to a predetermined thickness;
mounting the wafer onto a second carrier tape on the coated back-side surface;
removing the temporary carrier tape from the front-side surface of the wafer substrate; and
sawing the wafer substrate along active device boundaries and singulating the active devices.

2. The method as recited in claim 1, wherein the temporary covering includes: temporary carrier tape, resilient coating.

3. The method as recited in claim 2, wherein, prior to applying the temporary covering, the method further comprises,
applying and patterning a dielectric layer on the front-side surface of the wafer substrate;
applying and patterning an RDL layer;
applying and patterning a dielectric layer on the front-side surface of the wafer substrate;
applying and patterning the under bump metallization; and
applying bumps.

4. The method as recited in claim 1, wherein the post grind thickness is between about 4% to about 10% of the pre-grind thickness.

5. The method as recited in claim 4, where in the post grind thickness is at least 25 μm.

6. The method as recited in claim 5, wherein the resilient coating has a thickness in the range of about 30 μm to about 200 μm.

7. The method as recited in claim 5, wherein the wafer substrate is selected from one of the following: Si, GaAs, InP, SiC.

8. A method for preparing a silicon-on-insulator (SOI) substrate, for manufacturing IC devices, the SOI substrate having a front side surface and back-side surface opposite the front side surface, the method comprising:
providing an SOI substrate with active devices patterned on the front-side surface of the SOI substrate;
grinding down the back-side surface of the SOI substrate so as to obtain a first thickness of the SOI substrate;
protecting the front-side surface of the SOI substrate with an etch-resistant coating;
etching the back-side surface of the SOI substrate surface so as to obtain a final thickness of the SOI substrate; and
applying a resilient coating of a thickness to the back-side surface of the SOI substrate.

9. The method as recited in claim 8 further comprising, singulating the SOI substrate with active devices, into individual devices.

10. The method as recited in claim 8, wherein the final thickness is defined by a depth of a buried oxide layer etch stop.

11. The method as recited in claim 10,
wherein the first thickness obtained is about 25 μm; and
wherein the final thickness obtained is about 3 μm.

12. The method as recited in claim 11, wherein the thickness of the resilient coating is in the range of about 30 μm to about 200 μm.

13. An integrated circuit (IC) device for wafer-level chip-scale packaging (WLCSP) comprising:
a device die with a front-side surface with an active device and a back-side surface, wherein the back-side surface has been ground to a post-grind thickness; and
a resilient coating adhering to the back-side surface, the resilient coating having a thickness;
wherein the post-grind thickness of the device die and the thickness of the resilient coating are defined such that the coefficient of expansion of the IC device is similar to that of a printed circuit board (PCB) to which the IC device is mounted.

14. The IC device as recited in claim 13,
wherein on the front-side surface, the active device has under ball mounting (UBM) regions defined thereon; and
wherein solder balls are attached to the UBM regions; and
wherein the solder balls facilitate mounting of the IC device onto the PCB.
